(19) United States
(12) Patent Application Publication
(10) Pub. No.: US 2025/0214123 A1
(43) Pub. Date: Jul. 3, 2025

(54) METHOD OF TREATING SUBSTRATE

(71) Applicant: SEMES CO., LTD., Cheonan-si (KR)

(72) Inventors: Joon Ho WON, Suwon-si (KR); Hyeon Cheol LEE, Cheonan-si (KR)

(73) Assignee: SEMES CO., LTD., Cheonan-si (KR)

(21) Appl. No.: 19/004,977

(22) Filed: Dec. 30, 2024

(30) Foreign Application Priority Data
Dec. 28, 2023 (KR) 10-2023-0194240

(51) Int. Cl. B08B 13/00; B08B 1/12; B08B 3/02; B08B 7/00

(52) U.S. Cl. CPC B08B 13/00; B08B 3/024; B08B 1/12; B08B 7/0035; B08B 7/0071

(57) ABSTRACT

Disclosed is a method of treating a substrate, the method including: a substrate treating operation of treating a substrate with a component for treatment while moving an arm mounted with the component for treatment on the substrate rotating in accordance with a treatment recipe relative to the substrate; and a validating operation of validating an initial recipe received for use in the substrate treating operation prior to the substrate treating operation, in which the validating operation includes: a checking operation of partitioning a region on the substrate into a plurality of unit regions, and checking a treatment time during which each of the plurality of unit regions is directly treated by the component for treatment for a set time; and a determining operation of determining whether the treatment time in each of the plurality of unit regions checked in the checking operation is appropriate.

### CROSS-REFERENCE TO RELATED APPLICATIONS

This application claims priority to and the benefit of Korean Patent Application No. 10-2023-0194240 filed in the Korean Intellectual Property Office on Dec. 28, 2023, the entire contents of which are incorporated herein by reference.

### TECHNICAL FIELD

The present invention relates to a substrate treating method, and more particularly to a substrate treating method that validates a recipe applied to a substrate treating apparatus.

### BACKGROUND ART

To manufacture semiconductor devices, various processes, such as photography, deposition, ashing, etching, and ion implantation, are performed. Before and after these processes, a cleaning process is also performed to remove any particles left on the substrate.

The cleaning process may be broadly categorized into dry cleaning and wet cleaning, and wet cleaning, which is currently used in most semiconductor processes due to its relatively simple and cost-effective process, uses various chemical liquids to remove impurities.

The wet cleaning method may be categorized into batch type and single wafer type. The batch type is a method that removes contaminants by immersing multiple wafers at once in a cleaning bath containing a cleaning solution, but it has the disadvantage that it is difficult to respond to the trend of wafer enlargement and uses a lot of cleaning solution because a new cleaning bath needs to be installed accordingly when the wafers become larger. In addition, when a wafer in the cleaning bath is damaged during the cleaning process, it affects all wafers in the cleaning bath, which may cause defects in a large number of wafers, so it is gradually being applied less and less.

The single wafer type treats wafers as a single sheet and removes impurities by spraying a cleaning solution on the surface of a high-speed rotating wafer. The single wafer type removes impurities by utilizing the pressure applied to the cleaning solution by a spray device and the centrifugal force applied to the cleaning solution by the rotating substrate.

In the case of the single wafer type, a recipe is applied to treat the substrate. These recipes are created and modified by human experience. On the other hand, in general, when a substrate is treated, the rotation of the substrate and the movement of the arm occur simultaneously, so when an incorrect recipe is written, certain regions may be left untreated. There is a problem in that there is no standard to determine in advance whether the recipe is written correctly.

### SUMMARY OF THE INVENTION

The present invention has been made in an effort to provide a substrate treating method capable of efficiently treating a substrate.

The present invention has also been made in an effort to provide a substrate treating method that evaluates the appropriateness of a recipe used in a substrate treating apparatus before the recipe is used in the substrate treating apparatus.

The present invention has also been made in an effort to provide a substrate treating method capable of increasing the appropriateness of a recipe used in a substrate treating apparatus.

The problem to be solved by the present invention is not limited to the above-mentioned problems, and the problems not mentioned will be clearly understood by those skilled in the art from the descriptions below.

An exemplary embodiment of the present invention provides a method of treating a substrate, the method including: a substrate treating operation of treating a substrate with a component for treatment while moving an arm mounted with the component for treatment on the substrate rotating in accordance with a treatment recipe relative to the substrate; and a validating operation of validating an initial recipe received for use in the substrate treating operation prior to the substrate treating operation, in which the validating operation includes: a checking operation of partitioning a region on the substrate into a plurality of unit regions, and checking a treatment time during which each of the plurality of unit regions is directly treated by the component for treatment for a set time; and a determining operation of determining whether the treatment time in each of the plurality of unit regions checked in the checking operation is appropriate.

According to the exemplary embodiment, the set time may be a total time spent for treating the substrate in the substrate treating operation.

According to the exemplary embodiment, the method may further include receiving the initial recipe, in which the checking operation may be performed by simulation using a plurality of input factors included in the initial recipe.

According to the exemplary embodiment, the determining operation may include determining that the initial recipe is appropriate when the treatment time between the plurality of unit regions is within a set range, and performing the substrate treating operation by using the initial recipe as the treatment recipe.

According to the exemplary embodiment, the determining operation may include: a recipe modifying operation of determining that the initial recipe is inappropriate when the treatment time between the plurality of unit regions is outside a set range, and modifying the initial recipe to create a modified recipe; and a validation operation of validating the modified recipe, and the substrate treating operation may include treating the substrate by using the modified recipe as the treatment recipe.

According to the exemplary embodiment, the component for treatment may include a nozzle for discharging a treatment liquid onto the substrate or a nozzle for spraying a liquid onto the substrate in the form of mist.

According to the exemplary embodiment, the component for treatment may include a brush for cleaning the substrate by physical contact with the substrate.

According to the exemplary embodiment, the component for treatment may include an ultrasonic nozzle for applying ultrasonic waves to a liquid film formed on the substrate.

According to the exemplary embodiment, the component for treatment may include a light source for emitting light onto the substrate.

According to the exemplary embodiment, the component for treatment may include a heater for providing heat to the substrate.

According to the exemplary embodiment, the component for treatment may have a circular, ring, elliptical, or polygonal shape when viewed from below.

Another exemplary embodiment of the present invention provides a method of treating a substrate, the method including: receiving an initial recipe including substrate speed data regarding a rotation speed of the substrate, process data regarding a treatment process of the substrate, and data regarding a treating unit for treating the substrate; and performing a validation of the initial recipe, in which the performing of the validation of the initial recipe includes: obtaining treatment data, which is data concerning a time for which the treating unit treats the substrate by a plurality of unit regions on the substrate based on the initial recipe; and determining appropriateness of the initial recipe based on the treatment data.

According to the exemplary embodiment, the process data may include first acceleration time data, which is data relating to a time taken to accelerate a rotation speed of the substrate from a first rotation speed to a second rotation speed, and treatment time data, which is data relating to a time taken to process the substrate, and the data regarding a treating unit may include: target position data regarding a target position on the substrate of the treating unit; speed data regarding a set speed at which the treating unit moves to the target position; second acceleration time data, which is data regarding a time taken for the treating unit to accelerate to the set speed; second deceleration time data, which is data regarding a time taken for the treating unit to stop at the set speed; and waiting time data, which is data concerning a time for the treating unit to stay at the target position. According to the exemplary embodiment, the obtaining of the treatment data may include: converting the data contained in the initial recipe into time series data; performing a partition on the time series data based on unit time; obtaining, based on the partitioned time series data, count data, which is data for the number of times the treating unit passes the substrate by a plurality of unit regions on the substrate; and obtaining the treatment data based on the count data.

According to the exemplary embodiment, the determining of the appropriateness of the initial recipe based on the treatment data may include: obtaining, based on the treatment data, a plurality of unit regions among the plurality of unit regions of which the treatment time is equal to or longer than a preset time; and determining the appropriateness of the initial recipe based on whether a ratio of the plurality of unit regions in which the treatment time is equal to or longer than the preset time is equal to or larger than a preset value.

According to the exemplary embodiment, the method may further include: receiving spray volume data, which is data regarding an amount of treatment liquid sprayed by the treating unit based on a position of the substrate; and obtaining, based on the treatment data and the spray volume data, hitting force data, which is data concerning the amount by which the treating unit sprays a treatment liquid onto the substrate by a plurality of regions on the substrate.

According to the exemplary embodiment, the determining of the appropriateness of the initial recipe based on the treatment data may include determining the appropriateness of the initial recipe based on the treatment data and the hitting force data.

Still another exemplary embodiment of the present invention provides a method of treating a substrate, the method including: receiving an initial recipe; a substrate treating operation of treating a substrate with a component for treatment while moving an arm mounted with the component for treatment on the substrate rotating in accordance with a treatment recipe relative to the substrate; and a validating operation of validating an initial recipe received for use in the substrate treating operation prior to the substrate treating operation, in which the validating operation includes: a checking operation of partitioning a region on the substrate into a plurality of unit regions, and checking a treatment time for which each of the plurality of unit regions is directly treated by the component for treatment for a set time; and a determining operation of determining whether the treatment time in each of the plurality of unit regions checked in the checking operation is appropriate, the set time is a total time taken to treat the substrate in the substrate treating operation, the checking operation is performed by simulation by using a plurality of input factors included in the initial recipe, and the determining operation includes determining that the initial recipe is appropriate when the treatment time between the plurality of unit regions is within a set range, and determining that the initial recipe is inappropriate when the treatment time between the plurality of unit regions is outside the set range.

According to the exemplary embodiment, the component for treatment may include a brush for cleaning the substrate by physical contact with the substrate, a nozzle for discharging a treatment liquid onto the substrate, an ultrasonic nozzle for applying ultrasonic waves to a liquid film formed on the substrate, a light source for emitting light onto the substrate, and a heater for providing heat to the substrate, or a nozzle for spraying a liquid onto the substrate in the form of mist, and the component for treatment may have a circular, ring, elliptical, or polygonal shape when viewed from below.

According to the exemplary embodiment, the determining operation may further include: when it is determined that the initial recipe is inappropriate, modifying the initial recipe to create a modified recipe; and validating the modified recipe, and the substrate treating operation may include treating the substrate by using the initial recipe or the modified recipe as the treatment recipe.

According to the exemplary embodiments of the present invention, the nozzle occupies the substrate regardless of the position of the substrate, allowing the substrate to be treated uniformly.

According to the exemplary embodiments of the present invention, trial and error in recipe creation may be prevented by performing validation of the initial recipe.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

FIG. 1 is a top plan view illustrating a substrate treating apparatus according to a first exemplary embodiment of the present invention.

FIG. 2 is a cross-sectional view illustrating the exemplary embodiment of a liquid treating chamber according to the first exemplary embodiment of the present invention.

FIG. 3 is a flow diagram of a substrate treating method according to an exemplary embodiment of the present invention.

FIG. 4 is a flow diagram of a method of performing a validation of an initial recipe according to the exemplary embodiment of the present invention.

FIG. 5 is a flow diagram of a method of performing a check on an initial recipe, according to the exemplary embodiment of the present invention.

FIG. 6 is a diagram illustrating an example of converting a rotation speed of a substrate included in an initial recipe into time series data according to the exemplary embodiment of the present invention.

FIG. 7 is a flow diagram of a method of obtaining data regarding treatment time according to the exemplary embodiment of the present invention.

FIG. 8 is a diagram illustrating an example of a relative position of a nozzle according to rotation of a substrate according to the exemplary embodiment of the present invention.

FIG. 9 is a diagram illustrating an example of count data according to the exemplary embodiment of the present invention.

FIG. 10 is a diagram illustrating one example of treatment data according to the exemplary embodiment of the present invention.

FIG. 11 is a flow diagram of a method of determining appropriateness for an initial recipe according to the exemplary embodiment of the present invention.

FIG. 12 is a diagram illustrating the effect of the substrate treating method according to the exemplary embodiment of the present invention.

FIG. 13 is a cross-sectional view of a substrate treating apparatus according to a second exemplary embodiment of the present invention.

FIG. 14 is a cross-sectional view of a substrate treating apparatus according to a third exemplary embodiment of the present invention.

FIG. 15 is a cross-sectional view of a substrate treating apparatus according to a fourth exemplary embodiment of the present invention.

FIG. 16 is a cross-sectional view of a substrate treating apparatus according to a fifth exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the following, the present invention will be described hereinafter based on the fact that a substrate W to be treated is a wafer. Further, the present invention will be described hereinafter based on the fact that a pattern PA is formed on the substrate W to be treated. Further, the present invention will be described based on the fact that a substrate treating method is a method of manufacturing a semiconductor device.

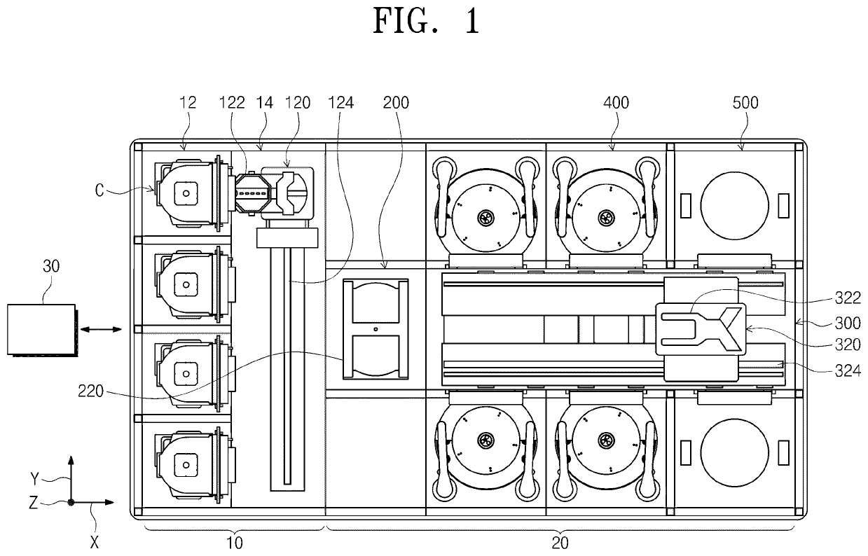

FIG. 1 is a top plan view illustrating a substrate treating apparatus 1 according to a first exemplary embodiment of the present invention.

Referring to FIG. 1, the substrate treating apparatus 1 includes an index module 10, a treating module 20, and a controller 30. When viewed from above, the index module 10 and the treating module 20 are disposed along one direction. Hereinafter, the direction in which the index module 10 and the treating module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers the substrate W from the container C in which the substrate W is accommodated to the treating module 20, and accommodates the substrate W that has been completely treated in the treating module 20 in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. A plurality of load ports 12 may be provided, and the plurality of load ports 12 may be disposed along the second direction Y.

As the container C, an airtight container, such as a Front Open Unified Pod (FOUP), may be used. The container C may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate W is placed, and the hand 122 may be provided to be movable forward and backward directions, rotatable about the third direction Z and movable along the third direction Z. A plurality of hands 122 are provided to be spaced apart in the vertical direction, and the hands 122 may move forwardly and backwardly independently of each other.

The treating module 20 includes a buffer unit 200, a transfer chamber 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid treating process of treating the substrate W with a liquid by supplying a liquid onto the substrate W. The drying chamber 500 performs a drying process of removing the liquid residual on the substrate W. The transfer chamber 300 transfers the substrate W between the buffer unit 200, the liquid treating chamber 400, and the drying chamber 500.

The buffer unit 200 includes a plurality of buffers 220 on which the substrate W is placed. The buffers 220 may be disposed to be spaced apart from each other along the third direction Z. The buffer 220 may be a substrate holder that supports the underside of the substrate W. The buffer 220 may be provided in the form of a support shelf that supports the underside of the substrate W.

A front face and a rear face of the buffer unit 200 are opened. The front face is a face facing the index module 10, and the rear face is a face facing the transfer chamber 300. The buffer unit 200 may be accessible by at least one of the index robot 120 and the transfer robot 320.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side portion of the transfer chamber 300. The liquid treating chamber 400 and the transfer chamber 300 may be sequentially disposed relative to the second direction Y. The drying chamber 500 and the transfer chamber 300 may be sequentially disposed relative to the second direction Y. The buffer unit 200 may be located at one end of the transfer chamber 300.

According to the example, the liquid treating chambers 400 are disposed on both sides of transfer chamber 300, and the drying chambers 500 are disposed on both sides of the transfer chamber 300, and the liquid treating chambers 400 may be disposed closer to the buffer unit 200 than the drying chambers 500. At one side of the transfer chamber 300, the liquid treating chambers 400 may be provided in an arrangement of A×B (each of A and B is 1 or a natural larger than 1) in the first direction X and the third direction Z. Further, at one side of the transfer chamber 300, the drying chambers 500 may be provided in number of C×D (each of C and D is 1 or a natural number larger than 1) in the first direction 92 and the third direction 96. Unlike the above, only the liquid treating chambers 400 may be provided on one side of the transfer chamber 300, and only the drying chambers 500 may be provided on the other side of the transfer chamber 300.

The transfer chamber 300 includes a transfer robot 320. A guide rail 324 of which a longitudinal direction is provided in the first direction X is provided in the transfer chamber 300, and the transfer robot 320 may be provided to be movable on the guide rail 324. The index robot 320 includes a hand 322 on which the substrate W is placed, and the hand 322 may be provided to be movable forward and backward directions, rotatable about the third direction Z and movable along the third direction Z. A plurality of hands 322 are provided to be spaced apart in the vertical direction, and the hands 322 may move forward and backward independently of each other.

The controller 30 may control the substrate treating apparatus 1. The controller 30 may include a process controller formed of a microprocessor (computer) that executes the control of the substrate treating apparatus 1, a user interface formed of a keyboard in which an operator performs a command input operation or the like in order to manage the substrate treating apparatus 1, a display for visualizing and displaying an operation situation of the substrate treating apparatus 1, and the like, and a storage unit storing a control program for executing the process executed in the substrate treating apparatus 1 under the control of the process controller or a program, that is, a treating recipe, for executing the process in each component according to various data and treating conditions. Further, the user interface and the storage unit may be connected to the process controller. The treatment recipe may be memorized in a storage medium in the storage unit, and the storage medium may be a hard disk, and may also be a portable disk, such as a CD-ROM or a DVD, or a semiconductor memory, such as a flash memory.

The controller 30 may control configurations of the substrate treating apparatus 1 to perform a substrate treating method described below. For example, the controller 30 may be provided with a recipe for controlling the liquid treating chamber 400 and the drying chamber 500 and determine the appropriateness of the provided recipe. When the controller 30 determines that the recipe is appropriate, the controller 30 may generate control commands to control the liquid treating chamber 400 and the drying chamber 500 based on the recipe.

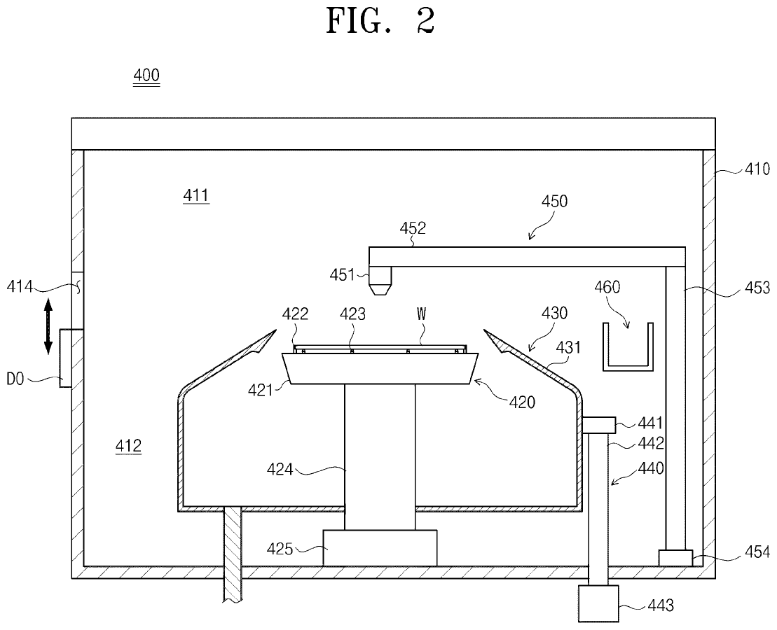

FIG. 2 is a diagram schematically illustrating the exemplary embodiment of the liquid treating chamber.

Referring to FIG. 2, the liquid treating chamber 400 according to the exemplary embodiment of the present invention may treat the substrate W by supplying the substrate W with a treatment liquid. The treatment liquid supplied to the substrate W may be a cleaning solution that cleans the substrate W. The cleaning solution may be deionized water or an organic solvent. The organic solvent may be a solvent containing alcohol. The organic solvent may be isopropyl alcohol (IPA).

The liquid treating chamber 400 may include a housing 410, a support unit 420, a bowl 430, a lifting unit 440, a liquid supply unit 440, and a nozzle waiting cup 460.

The housing 410 may provide a space in which the substrate W is treated, and a space in which some of the configurations of the liquid treating chamber 400 are arranged. The housing 410 may provide an upper space 411, which is a treatment space in which the substrate W is treated, and a lower space 412, which is located below the upper space 411.

On one side of the housing 410, an entrance opening 414 may be formed for the substrate W to be introduced into the upper space 411 and for the substrate W to be removed from the upper space 411. The entrance opening 414 may be selectively opened and closed by a door DO, which may be a shutter. The door DO may be configured to be movable in an up and down direction. For example, the door DO may be configured to be moved in an up and down direction by an electric motor, a pneumatic/hydraulic cylinder, or the like.

The support unit 420 may be configured to support and rotate the substrate W in the space provided by the housing 410. The support unit 420 may include a rotation plate 421, a rotation shaft 424, and a rotation driver 425.

The rotation plate 421 may have a substantially circular plate shape when viewed from above. The rotation plate 421 may have the shape of a top surface that is wide and a bottom surface that is narrow. In the rotation plate 421, a chuck pin 422 and a support pin 423 may be installed. The chuck pins 422 may be provided in plurality.

The chuck pins 422 may be configured to support the bottom face and the side portions of the edge of the substrate W. The chuck pins 422 may be configured to be movable in a direction that is closer to the center of the rotation plate 421 or a direction that is away from the center of the rotation plate 421, when viewed from above. The chuck pins 422 may be configured to be movable in a direction that is closer to the center of the rotation plate 421 or in a direction that is away from the center of the rotation plate 421 by a drive mechanism, such as a motor or cylinder, provided within the rotation plate 421. When the chuck pin 422 is moved in the direction closer to the center of the rotation plate 421 and is positioned in a chucking position, the substrate W may be chucked onto the rotation plate 421. Conversely, when the chuck pin 422 moves in the direction away from the center of the rotation plate 421 and is positioned in a de-chucking position, the substrate W may be de-chucked from the rotation plate 421.

The support pins 423 may be configured to support the bottom face of the substrate W. The support pins 423 may be provided in plurality, and may be configured to support different points on the bottom face of the substrate W, respectively. The support pins 423 may be arranged while being spaced apart from each other along the circumferential direction when viewed from above.

The lower portion of the rotation plate 421 may be coupled with the rotation shaft 424. The rotation shaft 424 may be rotated clockwise or counterclockwise by receiving drive force from the rotation driver 425, which may be a hollow motor.

The bowl 430 may provide a space in which the substrate W is treated. The bowl 430 may have a cup shape with an open top. The bowl 430 may function as a liquid receiving part to collect the treatment liquid that is dispersed from the substrate W when the liquid supply unit 450, described later, supplies the treatment liquid to the rotating substrate W.

The bowl 430 may include an outer bowl 431 and an inner bowl 432. The outer bowl 431 and the inner bowl 432 may include a bottom portion, a lateral portion extending upwardly from the bottom, and a top portion extending inclined from the lateral portion in a direction proximate to the rotation plate 421. The lateral portion may be coupled with the lifting unit 440 described later. The inner bowl 432 may be a bowl disposed on the inner side of the outer bowl 431.

The treatment liquid may be collected between the outer bowl 431 and the inner bowl 432. The collected treatment liquid may be discharged to the outside of the liquid treating chamber 400 via a line connected to the bottom portion of the outer bowl 431.

The lifting unit 440 may be configured to change the relative height of the bowl 430 and the rotation plate 421. The lifting unit 440 may be configured to move the bowl 430 in an up and down direction, thereby changing the relative height of the bowl 430 and the rotation plate 421. The lifting unit 440 may include a fixing bracket 441, a lifting shaft 442, and a lifting driver 443. The lifting driver 443, which may be a motor, or a pneumatic/hydraulic cylinder, may move the fixing bracket 441 connected to the lifting shaft 442 in the up and down direction. The fixing bracket 441 is coupled to a side portion of the outer bowl 431, and is capable of moving both the outer bowl 431 and the inner bowl 432 in the up and down direction.

The liquid supply unit 450 may supply the substrate W with a treatment liquid. The treatment liquid may be a cleaning solution that cleans the substrate W. The cleaning solution may be deionized water or an organic solvent. The organic solvent may be a solvent containing alcohol. Furthermore, the organic solvent may be isopropyl alcohol (IPA). The liquid supply unit 450 may include a nozzle 451, an arm 452, a movement shaft 453, and a movement driver 454. In the exemplary embodiment, the nozzle 451 may mist or discharge the treatment liquid onto the substrate W. The nozzle 451 may be a microdroplet or spray.

The nozzle 451 may be coupled to the arm 452. Here, the nozzle 451 may be a component for treatment and, when viewed from below, may be one of round, oval, hollow, or polygonal in cross-section.

The arm 452 may be coupled to the movement shaft 453. The movement shaft 453 may be rotated by the movement driver 454, which may be a motor. The movement shaft 453 may be rotatable. Thus, the arm 452 may be pivotable about an axis of rotation of the movement shaft 453.

The nozzle 451 may change its position between a process position and a standby position by rotation of the movement shaft 453. The process position may be a position at which the nozzle 451 faces the center of the substrate W placed on the rotation plate 421.

In the example described above, the liquid supply unit 450 is described and illustrated as being provided with a single liquid supply unit, but the liquid supply unit 450 may be provided with a plurality of liquid supply units. One of the liquid supply units 450 may be configured to supply deionized water, and another may be configured to supply isopropyl alcohol.

The nozzle waiting cup 460 may provide a waiting space for the nozzle 451 to wait. The nozzle 451 may be positioned in the standby position, that is, on the side above the nozzle standby cup 460, when the process is not in progress. The nozzle standby cup 460 may function as a liquid receiving part to receive a pre-discharged treatment liquid before the nozzle 451 initiates the process on the substrate W. Additionally, the nozzle standby cup 460 may function as a liquid receiving part to receive the treatment liquid that collects at the end portion of the nozzle 451 while the nozzle 451 is waiting.

Hereinafter, a substrate treating method according to an exemplary embodiment of the present invention will be described in detail.

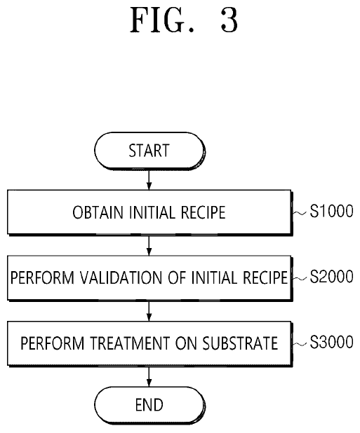

FIG. 3 is a flow diagram of a substrate treating method according to an exemplary embodiment of the present invention.

Referring to FIG. 3, the controller may obtain an initial recipe (S1000). The controller 30 may be provided with an initial recipe from an external source. For example, the controller 30 may receive an initial recipe from a user. The initial recipe may be formed as following Table 1.

TABLE 1

| | Substrate | Process data | | Nozzle arm data | | | | |
|---|---|---|---|---|---|---|---|---|
| | speed | Acceleration | Treatment | Position | Speed | Acceleration | Deceleration | Delay |
| Operation | data | time data | time data | data | data | time data | time data | data |
| 1 | 150 rev/min | 0 s | 0.8 s | (150, 0) | 5 mm/s | 0.1 s | 0.1 s | 0 s |
| 2 | 300 rev/min | 0.2 s | 1.0 s | (0, 150) | 7 mm/s | 0.2 s | 0.05 s | 0.2 s |

Referring to Table 1, the initial recipe may include substrate speed data, process data, and nozzle arm data at each operation. Each operation may be a respective operation for the substrate treating apparatus 1 to process the substrate W. For example, each operation may be a respective operation in which the liquid treating chamber 400 performs a liquid treatment on the substrate W. In Table 1, an initial recipe is illustrated to include only two operations, but this is by way of example and the present invention is not limited thereto. For example, the initial recipe may include N operations. The substrate speed data may be data about a rotation speed of the substrate W.

The process data may be data about the treatment of the substrate. The process data may include acceleration time data and treatment time data. The acceleration time data may be data regarding the time taken for a change in the rotation speed of the substrate W when the rotation speed of the substrate W changes in a corresponding operation compared to a operation before the corresponding operation, and the treatment time data may be data regarding the time taken for the substrate treating apparatus 1 to perform treatment on the substrate in the corresponding operation. The sum of the treatment time in each operation may be a total treatment time that the substrate treating apparatus 1 takes to perform treatment on the substrate.

The nozzle arm data may include position data, speed data, acceleration time data, deceleration time data, and delay data. The position data may be data regarding a target position of the nozzle 451 in a corresponding operation. The speed data may be data regarding a set speed at which the nozzle 451 is set to move to the target position in the corresponding operation. The acceleration time data may be data about the time taken to accelerate the movement speed of the nozzle 415 to the set speed in a corresponding operation. The deceleration time data may be data regarding the time taken for the nozzle 451 to decelerate from the set speed to zero to stop at the target position in the corresponding operation. The delay data may be data about the time the nozzle 451 waits at the target position.

In the exemplary embodiment, the controller 30 may further be provided with spray volume data. The spray volume data may be data regarding the amount of treatment liquid that the nozzle 451 sprays based on the position of the substrate W.

The controller may perform a validation of the initial recipe (S2000). The method of performing the validation of the initial recipe by the controller 30 will be described in more detail below.

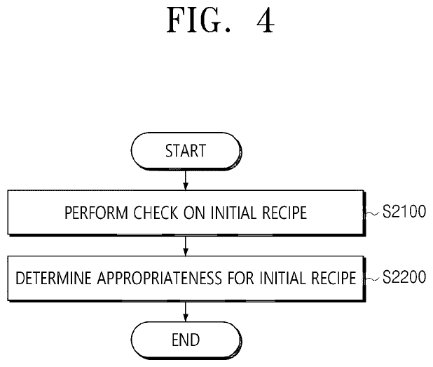

FIG. 4 is a flow diagram of a method of performing a validation of the initial recipe according to the exemplary embodiment of the present invention.

Referring to FIG. 4, the controller may perform a check on the initial recipe (S2100). The controller 30 may perform the check on the initial recipe by performing a simulation of the initial recipe. In more detail, the controller 30 may perform a check on the initial recipe.

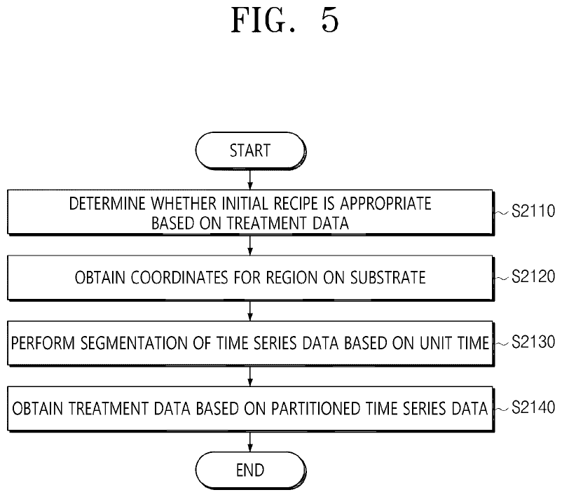

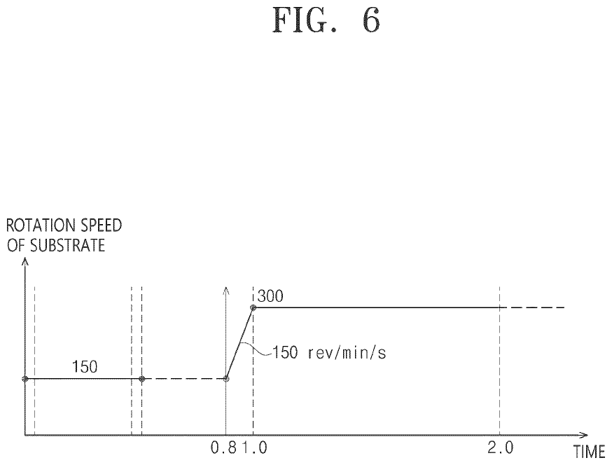

FIG. 5 is a flow diagram of a method of performing the check on the initial recipe, according to the exemplary embodiment of the present invention. FIG. 6 is a diagram illustrating an example of converting a rotation speed of a substrate included in the initial recipe into time series data according to the exemplary embodiment of the present invention.

Referring to FIG. 5, the controller may convert the data contained in the initial recipe to time series data (S2110). The controller 30 may convert the substrate speed data and the nozzle arm data into time series data based on the process data included in the initial recipe.

The controller 30 may convert the substrate speed data and the nozzle arm data at each operation into one time series data each. Here, the time series data may be data during a total treatment time that the substrate treating apparatus 1 takes to perform treatment on the substrate W.

Referring to FIG. 6, for example, the controller 30 may convert the substrate speed data at each operation in Table 1 into one time series data at the total treatment time, as illustrated in FIG. 6.

The controller may obtain coordinates for a region on the substrate (S2120). Here, the region on the substrate W may be a region where treatment is performed by the substrate treating apparatus 1. The controller may divide the region on the substrate into a plurality of unit regions, and may acquire coordinates for the plurality of unit regions. Here, the unit region may be a shape of a grid. For example, the controller 30 may mesh a region on the substrate and obtain coordinates in the meshed region.

The controller may perform a segmentation of the time series data based on the unit time (S2130). The controller 30 may perform segmentation on the time-series converted substrate speed data and nozzle arm data in operation S2110 based on unit time. The controller 30 may perform the partition on the time series data at each unit time. The unit time may be preset and may be a time that is less than the total treatment time. For example, the preset unit time may be td, and the time series data may be partitioned into N pieces.

The controller may obtain treatment data based on the partitioned time series data (S2140). The method of obtaining the treatment data by the controller 30 will be described in detail below.

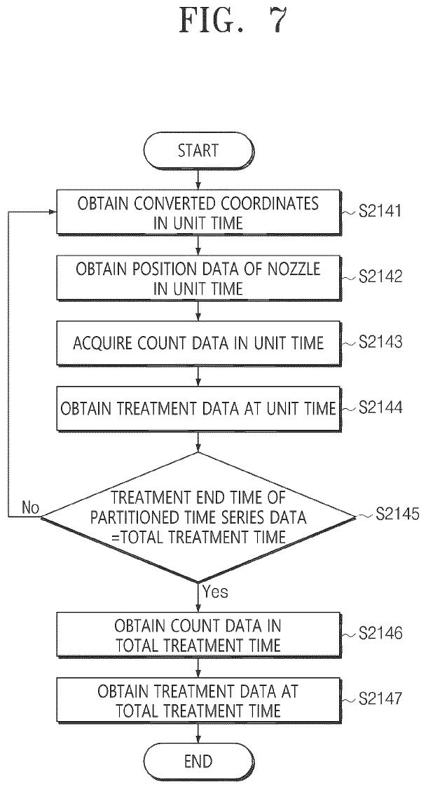

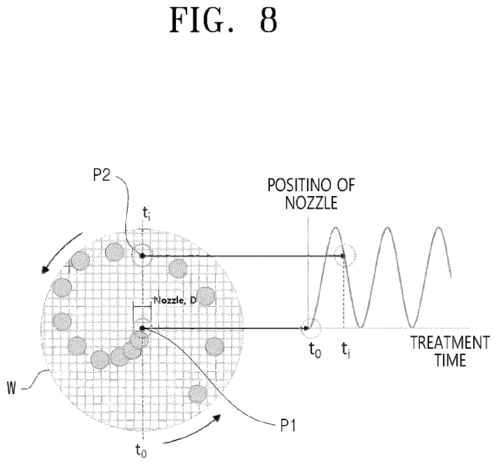

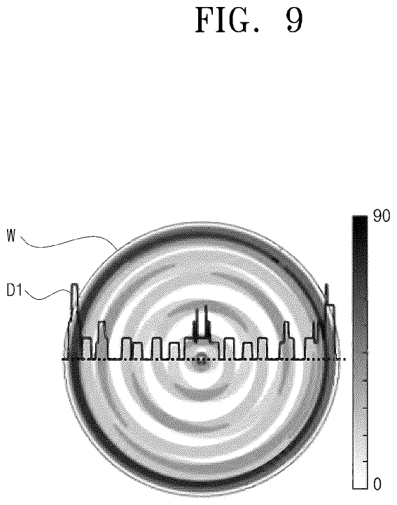

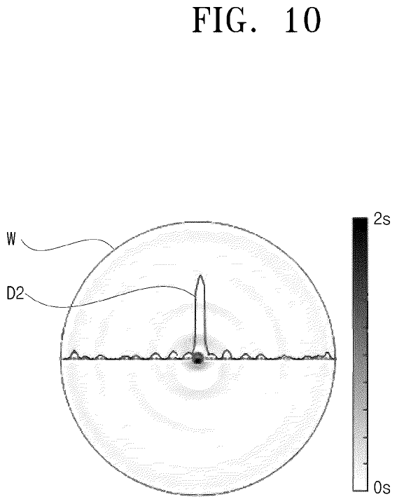

FIG. 7 is a flow diagram of a method of obtaining data regarding treatment time according to the exemplary embodiment of the present invention. FIG. 8 is a diagram illustrating an example of a relative position of a nozzle according to rotation of a substrate according to the exemplary embodiment of the present invention. FIG. 9 is a diagram illustrating an example of count data according to the exemplary embodiment of the present invention. FIG. 10 is a diagram illustrating one example of treatment data according to the exemplary embodiment of the present invention.

Referring to FIG. 7, the controller may obtain the converted coordinates in unit time (S2141).

The coordinates obtained in operation S2120 may be converted as the substrate W rotates. The controller 30 may obtain the converted coordinates based on the substrate speed data included in the segmented time series data.

The controller may obtain position data of the nozzle in unit time (S2142). The controller 30 may obtain position data of the nozzle 451 in unit time based on the partitioned time series data and the coordinates obtained in operation S2141. Here, the position data of the nozzle 451 may be data regarding a relative position of the nozzle 451 according to a rotation of the substrate W. Referring to FIG. 8, for example, when the treatment start time is t₀, the treatment end time is tᵢ, and the position of the nozzle 451 at t₀ is P1 for the partitioned time series data, the controller 30 acquires P2 as the position data of the nozzle 451 at tᵢ.

The controller may acquire count data in unit time (S2143). The controller 30 may obtain the count data in unit time based on the position data of the nozzle obtained in operation S2142. The count data in unit time data may be data regarding the number of times the nozzle 451 passes a plurality of unit regions on the substrate per unit time. Here, the plurality of unit regions on the substrate may be coordinates on the substrate associated with the plurality of unit regions on the substrate.

Based on the count data at the unit time, the controller may obtain treatment data at the unit time (S2144). The treatment data in unit time may be data representing the time the nozzle 451 treats the substrate per unit time, per the plurality of unit regions on the substrate. The time that the nozzle 451 treats the substrate may be the time that the nozzle 451 overlaps the substrate.

In the exemplary embodiment, when the controller 30 is further provided with the spray volume data of the nozzle 451 in S1000, the controller 30 may further obtain hitting force data at unit time of the nozzle 415 based on the treatment data and the spray volume data in unit time. The hitting force data in unit time may be data representing the amount of liquid sprayed by the nozzle 451 per unit time per segmented region on the substrate.

The controller compares the total treatment time and the treatment end time of the partitioned time series data (S2145). When the total treatment time and the treatment end time of the partitioned time series data are the same (YES in S2145), the controller 30 may obtain the count data in the total treatment time (S2146). The count data in the total treatment time may be data regarding the number of times the nozzle 451 passes the plurality of unit regions during the total treatment time.

The controller 30 may obtain the count data in the total treatment time by summing the count data in a plurality of unit times. For example, the controller 30 may obtain the count data in the total treatment time by summing the count data in N unit times.

Referring to FIG. 9, for example, the count data in the total treatment time may be data in which regions of the substrate are marked with different colors based on the number of times the substrate nozzle 451 passes each of the plurality of unit regions, and may include cross-section data (D1).

The controller may obtain treatment data at the total treatment time (S2147). Here, the treatment data in the total treatment time may be data regarding the time that the nozzle 451 has processed a plurality of unit regions during the total treatment time. The controller 30 may obtain the treatment data in the total treatment time by summing the treatment data in the plurality of unit times. For example, the controller 30 may obtain the treatment data of the total treatment time by summing the treatment data of N unit times.

Referring to FIG. 10, for example, the second treatment data may be data in which regions of the substrate are marked with different colors based on the time that the substrate nozzle 451 has processed each of the plurality of unit regions, and may include cross-sectional data D2.

In the exemplary embodiment, in S2144, when the controller 30 has obtained the hitting force data in the unit time, the controller 30 may further obtain hitting force data in the total treatment time. The hitting force data in the total treatment time may be data regarding the amount of liquid that the nozzle 451 sprays into each of the plurality of unit regions during the total treatment time. The controller 30 may obtain the hitting force data in the total treatment time by summing the hitting force data from the plurality of unit times.

Referring again to FIG. 7, when the total treatment time and the treatment end time of the partitioned time series data are the same (NO in S2145), the controller 30 may return to S2141 to obtain the converted coordinates in the unit time.

Referring again to FIG. 4, the controller may determine appropriateness for the initial recipe (S2200). The method of determining, by the controller 30, the appropriateness for the initial recipe will be described below.

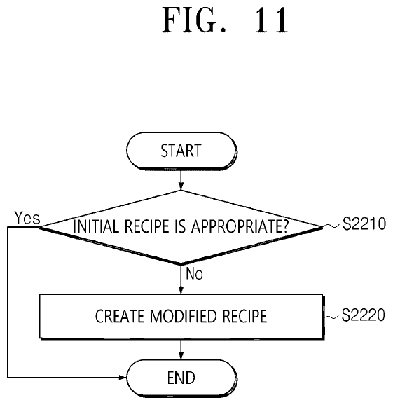

FIG. 11 is a flow diagram of a method of determining appropriateness for the initial recipe according to the exemplary embodiment of the present invention.

Referring to FIG. 11, the controller 30 may determine whether the initial recipe is appropriate based on the treatment data (S2210). The controller 30 may determine whether the initial recipe is appropriate based on treatment data in the total treatment time obtained in operation S2146. The controller 30 may extract the regions whose treatment times are within a preset time range from the plurality of regions on the substrate. The controller 30 may determine that the initial recipe is appropriate when the number of extracted regions is equal to or greater than a preset value.

When the initial recipe is determined to be appropriate (YES in S2210), the controller 30 may terminate the determination of appropriateness for the initial recipe.

When the initial recipe is not determined to be appropriate (NO in S2210), the controller 30 may modify the initial recipe to create a modified recipe (S2220). The controller 30 may create the modified recipe by changing at least one of the plurality of data included in the initial recipe.

Further, the controller 30 may determine the appropriateness of the modified recipe via operations S2100 and S2200 described above. When the modification recipe is not appropriate, the controller 30 may recreate the modified recipe and determine the appropriateness of the recreated modified recipe via operations S2100 and S2200 above.

Referring again to FIG. 3, the controller may instruct the substrate treating apparatus to perform treatment on the substrate (S3000). The controller 30 may instruct the substrate treating apparatus to perform treatment on the substrate W based on the initial recipe or the modified recipe. For example, the controller 30 may instruct the liquid treating chamber 400 to perform the treatment on the substrate W.

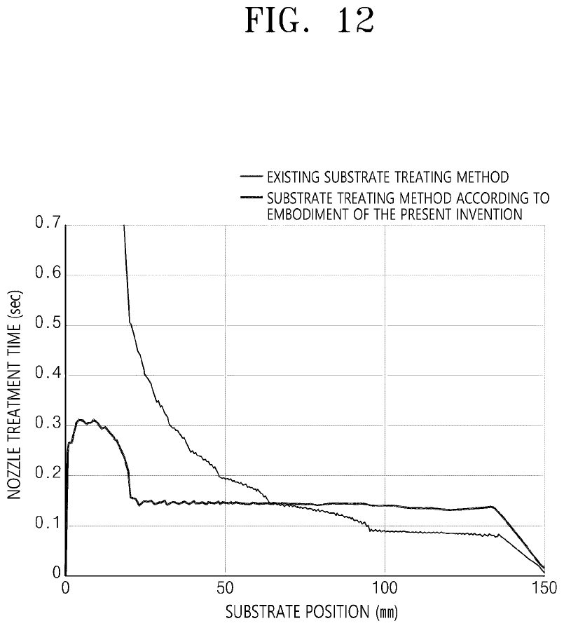

FIG. 12 is a diagram illustrating the effect of the substrate treating method according to the exemplary embodiment of the present invention.

FIG. 12 is a graph for comparing the treatment time of a nozzle per substrate location when following the existing substrate treating method and the treatment time of a nozzle per substrate location when following the substrate treating method according to the exemplary embodiment of the present invention. Here, the case of following the substrate treating method according to the exemplary embodiment of the present invention may be a case where an optimal recipe (e.g., a modified recipe) is obtained by performing a validation of the recipe by the method described above.

Referring to FIG. 12, it may be seen that in the existing substrate treating method, the treatment time of the nozzle is not constant for each substrate location because the treatment time of the nozzle decreases toward the periphery of the substrate, but in the substrate treating method according to the exemplary embodiment of the present invention, the treatment time of the nozzle is constant for each substrate location compared to the existing substrate treating method.

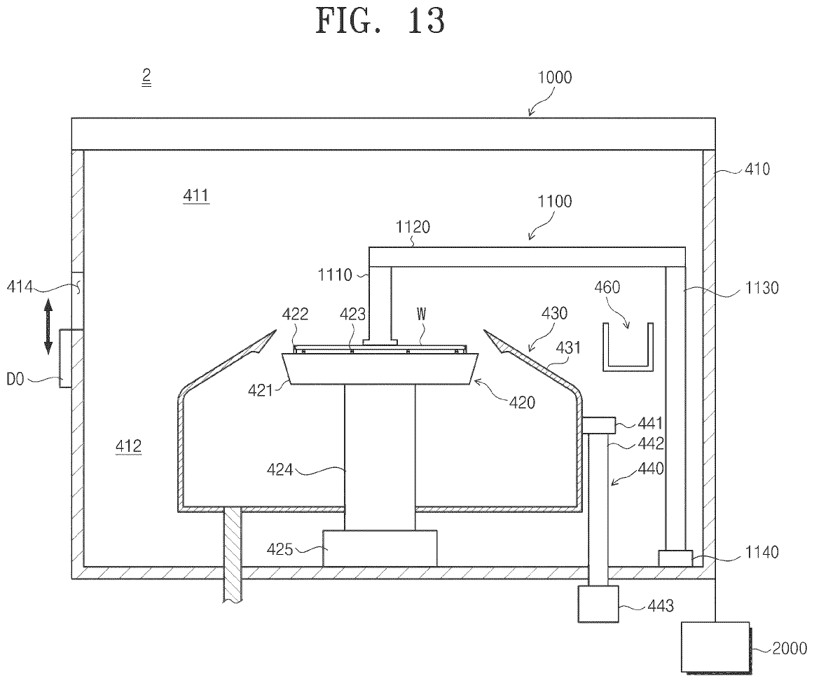

FIG. 13 is a cross-sectional view of a substrate treating apparatus according to a second exemplary embodiment of the present invention.

Referring to FIG. 13, a substrate treating apparatus 2 according to another exemplary embodiment of the present invention may include a cleaning chamber 1000 and a controller 2000. The cleaning chamber 1000 may physically clean the substrate W. The cleaning chamber 1000 may include a housing 410, a support unit 420, a bowl 430, a lifting unit 440, and a cleaning unit 1100. The cleaning unit 1100 may clean the substrate W. The cleaning unit 1100 may include a brush 1110, an arm 1120, a movement shaft 1130, and a movement driver 1140. The brush 1110 may be a component for treatment and may be coupled to the arm 1120. When viewed from below, the brush 1111 may be one of circular, oval, hollow, or polygonal in cross-section. The arm 1120, the movement shaft 1130, and the movement driver 1140 may be the same as the arm 452, the movement shaft 453, and the movement driver 454 of FIG. 2. Further, the controller 2000 may be configured identically to the controller 30 of FIG. 2. In this case, the initial recipe of Table 1 may further include information about a movement speed of the brush, the area of contact between the brush and the substrate.

The controller 2000 may control the substrate treating apparatus 2 in the manner described above in FIGS. 2 to 12. That is, the controller 2000 may control the substrate treating apparatus 2 such that the brush 1111 cleans the substrate W regardless of the position of the substrate W.

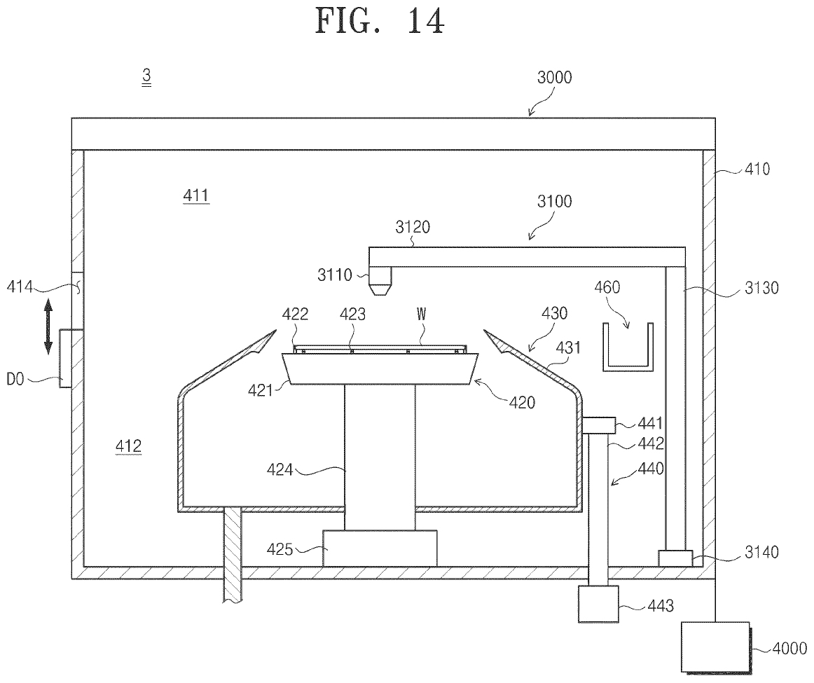

FIG. 14 is a cross-sectional view of a substrate treating apparatus according to a third exemplary embodiment of the present invention.

Referring to FIG. 14, a substrate treating apparatus 3 according to another exemplary embodiment of the present invention may include an ultrasonic chamber 3000 and a controller 4000. The ultrasonic chamber 3000 may include a housing 410, a support unit 420, a bowl 430, a lifting unit 440, and an ultrasonic supply unit 3100, and a nozzle waiting cup 460.

The ultrasonic unit 3100 may apply ultrasonic waves to the substrate W. Here, a liquid film may be formed on the substrate W. The ultrasonic unit 3100 may include an ultrasonic nozzle 3110, an arm 3120, a movement shaft 3130, and a movement driver 3140. The ultrasonic nozzle 3110 may be a component for treatment, and may be coupled to the arm 3120. When viewed from below, the ultrasonic nozzle 3110 may be one of circular, oval, hollow, or polygonal in cross-section. The arm 3120, the movement shaft 3130, and the movement driver 3140 may be the same as the arm 452, the movement shaft 453, and the movement driver 454 of FIG. 2. Further, the controller 4000 may be configured identically to the controller 30 of FIG. 2. In this case, the initial recipe may further include information about an operation time of the ultrasonic nozzle or an ultrasonic application amount of the ultrasonic nozzle.

The controller 4000 may control the substrate treating apparatus 3 in the manner described above in FIGS. 2 to 12. That is, the controller 4000 may control the substrate treating apparatus 3 such that the ultrasonic nozzle 3110 of the substrate treating apparatus 3 is capable of providing ultrasonic waves to the substrate W regardless of the position of the substrate W.

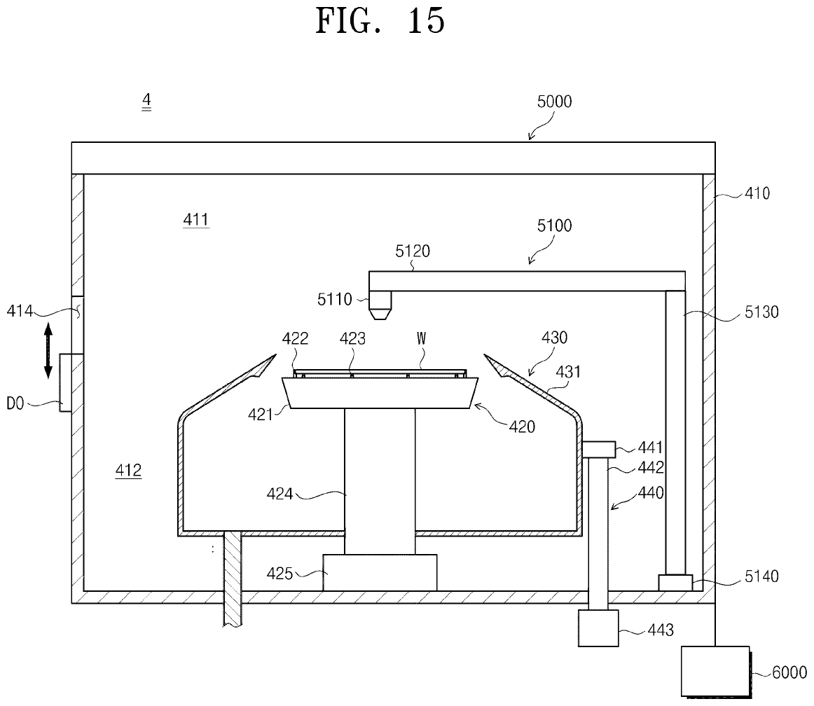

FIG. 15 is a cross-sectional view of a substrate treating apparatus according to a fourth exemplary embodiment of the present invention.

A substrate treating apparatus 4 according to another exemplary embodiment of the present invention may include a heating chamber 5000 and a controller 8000. The heating chamber 5000 may include a housing 410, a support unit 420, a bowl 430, a lifting unit 440, and a heating unit 5100.

The heating unit 5100 may provide heat to the substrate W to heat the substrate W. The heating unit 5100 may include a heater 5110, an arm 5120, a movement shaft 5130, and a movement driver 5140. The heater 5110 may be a component for treatment and may be coupled to the arm 3120. When viewed from below, the heater 5110 may be one of circular, oval, hollow, or polygonal in cross-section. The arm 5120, the movement shaft 5130, and the movement driver 5140 may be the same as the arm 452, the movement shaft 453, and the movement driver 454 of FIG. 2. Further, the controller 6000 may be configured identically to the controller 30 of FIG. 2. In this case, the initial recipe may further include information about the temperature of the heat provided to the substrate by the heater.

The controller 6000 may control the substrate treating apparatus 3 in the manner described above in FIGS. 2 to 12. In other words, the controller 6000 may control the substrate treating apparatus 3 such that the heater 5110 of the substrate treating apparatus 3 may heat the substrate W regardless of the position of the substrate W.

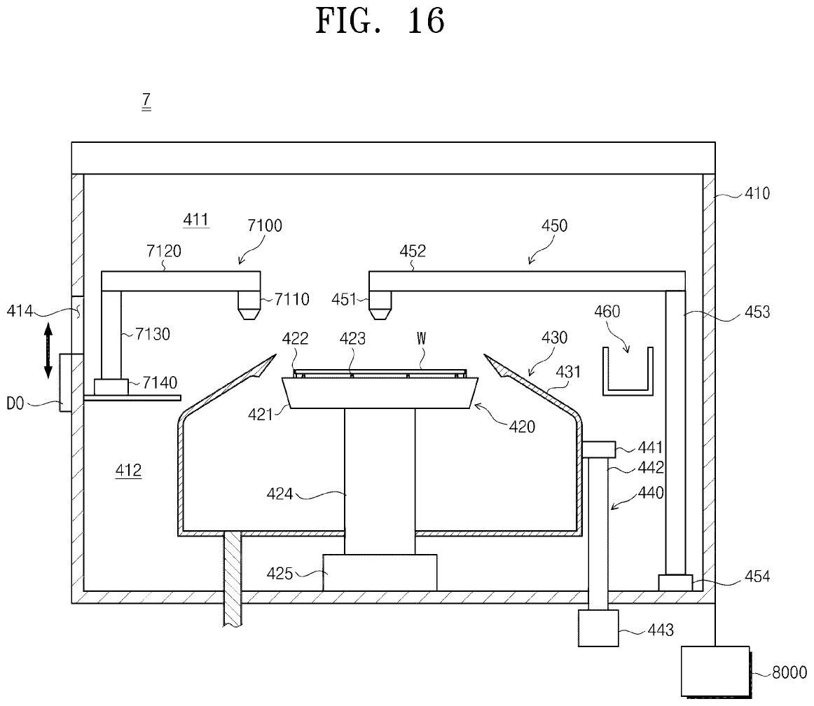

FIG. 16 is a cross-sectional view of a substrate treating apparatus according to a fifth exemplary embodiment of the present invention.

Referring to FIG. 16, a substrate treating apparatus 5 according to another exemplary embodiment of the present invention may include a liquid treating chamber 7000 and a controller 8000. The liquid treating chamber 7000 may include a housing 610, a support unit 620, a bowl 630, a lifting unit 640, a liquid supply unit 650, a nozzle waiting cup 660, and a lamp unit 7100.

The lamp unit 7100 may increase a temperature of the substrate surface (photoresist) during a substrate surface treatment process, and emit light onto the substrate for reactivity with the ozone treatment fluid and activation of OH radicals. The lamp unit 7100 may include a light source 7110, an arm 7120, a movement shaft 5130, and a movement driver 7140. The light source 7110 may be a component for treatment and may be coupled to the arm 7120. When viewed from below, the lamp 110 may be one of circular, oval, hollow, or polygonal in cross-section. The arm 7120, the movement shaft 7130, and the movement driver 7140 may be the same as the arm 452, the movement shaft 453, and the movement driver 454 of FIG. 2. Further, the controller 8000 may be configured identically to the controller 50 of FIG. 2. In this case, the initial recipe may further include information about the intensity of light emitted by the light source.

The controller 8000 may control the substrate treating apparatus 5 in the manner described above in FIGS. 2 to 12. In other words, the controller 8000 may control the substrate treating apparatus 5 such that the light source 7110 of the substrate treating apparatus 5 may irradiate the substrate W regardless of the location of the substrate W.

The foregoing detailed description illustrates the present invention. Furthermore, the foregoing is an illustrative description of a preferred exemplary embodiment of the present invention, and the invention is intended for use in a variety of other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A method of treating a substrate, the method comprising:
a substrate treating operation of treating a substrate with a component for treatment while moving an arm mounted with the component for treatment on the substrate rotating in accordance with a treatment recipe relative to the substrate; and
a validating operation of validating an initial recipe received for use in the substrate treating operation prior to the substrate treating operation,
wherein the validating operation includes:
a checking operation of partitioning a region on the substrate into a plurality of unit regions, and checking a treatment time during which each of the plurality of unit regions is directly treated by the component for treatment for a set time; and
a determining operation of determining whether the treatment time in each of the plurality of unit regions checked in the checking operation is appropriate.

2. The method of claim 1, wherein the set time is a total time spent for treating the substrate in the substrate treating operation.

3. The method of claim 1, further comprising:
receiving the initial recipe,
wherein the checking operation is performed by simulation using a plurality of input factors included in the initial recipe.

4. The method of claim 1, wherein the determining operation includes determining that the initial recipe is appropriate when the treatment time between the plurality of unit regions is within a set range, and performing the substrate treating operation by using the initial recipe as the treatment recipe.

5. The method of claim 1, wherein the determining operation includes:
a recipe modifying operation of determining that the initial recipe is inappropriate when the treatment time between the plurality of unit regions is outside a set range, and modifying the initial recipe to create a modified recipe; and
a validation operation of validating the modified recipe, and
the substrate treating operation includes treating the substrate by using the modified recipe as the treatment recipe.

6. The method of claim 1, wherein the component for treatment includes a nozzle for discharging a treatment liquid onto the substrate or a nozzle for spraying a liquid onto the substrate in the form of mist, and
the initial recipe includes information about an amount of treatment liquid discharged from the nozzle.

7. The method of claim 1, wherein the component for treatment includes a brush for cleaning the substrate by physical contact with the substrate, and
the initial recipe includes information about a movement speed of the brush, an area of contact between the brush and the substrate.

8. The method of claim 1, wherein the component for treatment includes an ultrasonic nozzle for applying ultrasonic waves to a liquid film formed on the substrate, and
the initial recipe includes information about an operation time of the ultrasonic nozzle or an ultrasonic application amount of the ultrasonic nozzle.

9. The method of claim 1, wherein the component for treatment includes a light source for emitting light onto the substrate, and
the initial recipe includes information about an intensity of the light emitted by the light source.

10. The method of claim 1, wherein the component for treatment includes a heater for providing heat to the substrate, and
the initial recipe includes information about a temperature of heat provided to the substrate by the heater.

11. The method of claim 1, wherein the component for treatment has a circular, ring, elliptical, or polygonal shape when viewed from below.

12. A method of treating a substrate, the method comprising:
receiving an initial recipe including substrate speed data regarding a rotation speed of the substrate, process data regarding a treatment process of the substrate, and data regarding a treating unit for treating the substrate; and
performing a validation of the initial recipe,
wherein the performing of the validation of the initial recipe includes:
obtaining treatment data, which is data concerning a time for which the treating unit treats the substrate by a plurality of unit regions on the substrate based on the initial recipe; and
determining appropriateness of the initial recipe based on the treatment data.

13. The method of claim 12, wherein the process data includes first acceleration time data, which is data relating to a time taken to accelerate a rotation speed of the substrate from a first rotation speed to a second rotation speed, and treatment time data, which is data relating to a time taken to process the substrate, and
the data regarding a treating unit includes:
target position data regarding a target position on the substrate of the treating unit;
speed data regarding a set speed at which the treating unit moves to the target position;
second acceleration time data, which is data regarding a time taken for the treating unit to accelerate to the set speed;
second deceleration time data, which is data regarding a time taken for the treating unit to stop at the set speed; and
waiting time data, which is data concerning a time for the treating unit to stay at the target position.

14. The method of claim 12, wherein the obtaining of the treatment data includes:
converting the data contained in the initial recipe into time series data;
performing a partition on the time series data based on unit time;
obtaining, based on the partitioned time series data, count data, which is data for the number of times the treating unit passes the substrate by a plurality of unit regions on the substrate; and
obtaining the treatment data based on the count data.

15. The method of claim 12, wherein the determining of the appropriateness of the initial recipe based on the treatment data includes:
obtaining, based on the treatment data, a plurality of unit regions among the plurality of unit regions of which the treatment time is equal to or longer than a preset time; and
determining the appropriateness of the initial recipe based on whether a ratio of the plurality of unit regions in which the treatment time is equal to or longer than the preset time is equal to or larger than a preset value.

16. The method of claim 12, further comprising:
receiving spray volume data, which is data regarding an amount of treatment liquid sprayed by the treating unit based on a position of the substrate; and
obtaining, based on the treatment data and the spray volume data, hitting force data, which is data concerning the amount by which the treating unit sprays a treatment liquid onto the substrate by a plurality of regions on the substrate.

17. The method of claim 16, wherein the determining of the appropriateness of the initial recipe based on the treatment data includes determining the appropriateness of the initial recipe based on the treatment data and the hitting force data.

18. A method of treating a substrate, the method comprising:
receiving an initial recipe;
a substrate treating operation of treating a substrate with a component for treatment while moving an arm mounted with the component for treatment on the substrate rotating in accordance with a treatment recipe relative to the substrate; and
a validating operation of validating an initial recipe received for use in the substrate treating operation prior to the substrate treating operation,
wherein the validating operation includes:
a checking operation of partitioning a region on the substrate into a plurality of unit regions, and checking a treatment time for which each of the plurality of unit regions is directly treated by the component for treatment for a set time; and
a determining operation of determining whether the treatment time in each of the plurality of unit regions checked in the checking operation is appropriate,
the set time is a total time taken to treat the substrate in the substrate treating operation,
the checking operation is performed by simulation by using a plurality of input factors included in the initial recipe, and
the determining operation includes determining that the initial recipe is appropriate when the treatment time between the plurality of unit regions is within a set range, and determining that the initial recipe is inappropriate when the treatment time between the plurality of unit regions is outside the set range.

19. The method of claim 18, wherein the component for treatment includes a brush for cleaning the substrate by physical contact with the substrate, a nozzle for discharging a treatment liquid onto the substrate, an ultrasonic nozzle for applying ultrasonic waves to a liquid film formed on the substrate, a light source for emitting light onto the substrate, and a heater for providing heat to the substrate, or a nozzle for spraying a liquid onto the substrate in the form of mist, and
the component for treatment has a circular, ring, elliptical, or polygonal shape when viewed from below.

20. The method of claim 18, wherein the determining operation further includes:
when it is determined that the initial recipe is inappropriate, modifying the initial recipe to create a modified recipe; and
validating the modified recipe, and
the substrate treating operation includes treating the substrate by using the initial recipe or the modified recipe as the treatment recipe.
